(19) United States
(12) Patent Application Publication
(10) Pub. No.: US 2025/0216876 A1
(43) Pub. Date: Jul. 3, 2025

(54) METHOD OF STABILIZING OUTPUT VOLTAGE OF VOLTAGE REGULATOR, ELECTRONIC DEVICE AND STORAGE DEVICE

(71) Applicant: SAMSUNG ELECTRONICS CO., LTD., Suwon-si (KR)

(72) Inventors: Jihong Kim, Suwon-si (KR); Minseok Kim, Suwon-si (KR); Jeonghoon Yoon, Suwon-si (KR)

(21) Appl. No.: 18/747,033

(22) Filed: Jun. 18, 2024

(30) Foreign Application Priority Data
Dec. 28, 2023 (KR) 10-2023-0194329

(51) Int. Cl. G05F 1/567; G05F 1/575

(52) U.S. Cl. CPC G05F 1/567; G05F 1/575

(57) ABSTRACT

An electronic device includes a voltage regulator configured to generate an output voltage through an output node by converting an input voltage, a load device configured to operate based on the output voltage as a power supply voltage, an output capacitor connected to the output node and having a fixed capacitance, a capacitance controller configured to generate a plurality of capacitance control signals based on a state signal indicating an operation state of the electronic device, and a variable capacitance circuit connected to the output node and having a capacitance that changes based on the plurality of capacitance control signals. Abnormal operations may be prevented and performance of the electronic device including the voltage regulator may be enhanced by changing the capacitance of the output node of the voltage regulator depending on the operation state of the electronic device using the variable capacitance circuit.

### CROSS-REFERENCE TO RELATED APPLICATION

This U.S. non-provisional application claims priority under 35 USC § 119 to Korean Patent Application No. 10-2023-0194329, filed on Dec. 28, 2023, in the Korean Intellectual Property Office (KIPO), the disclosure of which is incorporated by reference herein in its entirety.

### BACKGROUND

An electronic device such as a storage device includes a voltage regulator that converts an input voltage to generate an output voltage and various load devices that are powered by the output voltage. Increased fluctuation or ripple in the output voltage may cause malfunction of the load devices operating based on the output voltage, resulting in degraded performance of the electronic device.

### SUMMARY

Some implementations provide a method of stabilizing an output voltage of a voltage regulator, an electronic device and a storage device, capable of reducing fluctuation in the output voltage of the voltage regulator.

According to some implementations, an electronic device includes a voltage regulator configured to generate an output voltage through an output node by converting an input voltage, a load device configured to operate based on the output voltage as a power supply voltage, an output capacitor connected to the output node and having a fixed capacitance, a capacitance controller configured to generate a plurality of capacitance control signals based on a state signal indicating an operation state of the electronic device, and a variable capacitance circuit connected to the output node and having a capacitance that changes based on the plurality of capacitance control signals.

According to some implementations, a storage device includes a nonvolatile memory device configured to store data, a storage controller configured to control the nonvolatile memory device, a voltage regulator configured to generate an output voltage through an output node by converting an input voltage and supply the output voltage to the nonvolatile memory device and the storage controller, an output capacitor connected to the output node and having a fixed capacitance, a capacitance controller configured to generate a plurality of capacitance control signals based on a state signal indicating an operation state of the electronic device, and a variable capacitance circuit connected to the output node and having a capacitance that changes based on the plurality of capacitance control signals.

According to some implementations, a method of stabilizing an output voltage of a voltage regulator, includes, generating, using a voltage regulator, an output voltage through an output node of the voltage regulator by converting an input voltage, generating a state signal indicating an operation state of an electronic device, generating a plurality of capacitance control signals based on the state signal, changing, using a variable capacitance circuit connected to the output node, a capacitance of the output node based on the plurality of capacitance control signals.

The method of stabilizing the output voltage of the voltage regulator according to some implementations may prevent abnormal operations and enhance performance of the electronic device including the voltage regulator by changing the capacitance of the output node of the voltage regulator depending on the operation state of the electronic device using the variable capacitance circuit.

### BRIEF DESCRIPTION OF THE DRAWINGS

Implementations of the present disclosure will be more clearly understood from the following detailed description taken in conjunction with the accompanying drawings.

FIG. 1 is a block diagram illustrating an electronic device according to some implementations.

FIG. 2 is a diagram illustrating some implementations of a variable capacitance circuit included in the electronic device of FIG. 1.

FIGS. 3 and 4 are diagrams illustrating some implementations of capacitance groups included in the variable capacitance circuit of FIG. 2.

FIG. 5 is a flowchart illustrating a method of stabilizing an output voltage of a voltage regulator according to some implementations.

FIG. 6 is a flowchart illustrating a method of stabilizing an output voltage of a voltage regulator based on an operation temperature of an electronic device according to some implementations.

FIG. 7 is a flowchart illustrating some implementations of capacitance control signals according to the method of FIG. 6.

FIG. 8 is a diagram for describing a method of stabilizing an output voltage of a voltage regulator based on an operation temperature of an electronic device according to some implementations.

FIG. 9 is a block diagram illustrating a storage system according to some implementations.

FIG. 10 is a block diagram illustrating a storage controller according to some implementations.

FIG. 11 is a block diagram illustrating a nonvolatile memory device according to some implementations.

FIG. 12 is a block diagram illustrating a memory cell array included in the nonvolatile memory device of FIG. 11.

FIG. 13 is a circuit diagram illustrating an equivalent circuit of a memory block included in the memory cell array of FIG. 12.

FIG. 14 is a flowchart illustrating a method of stabilizing an output voltage of a voltage regulator based on an occupation state of a command queue included in a storage device according to some implementations.

FIGS. 15A and 15B are diagrams illustrating an example configuration of a storage controller included in a storage device according to some implementations.

FIGS. 16A and 16B are diagrams for describing a method of stabilizing an output voltage of a voltage regulator based on an occupation state of a command queue included in a storage device according to some implementations.

FIG. 17 is a flowchart illustrating a method of stabilizing an output voltage of a voltage regulator during a power-on sequence of an electronic device according to some implementations.

FIG. 18 is a timing diagram illustrating a method of stabilizing an output voltage of a voltage regulator during a power-on sequence of an electronic device according to some implementations.

FIG. 19 is a flowchart illustrating a method of stabilizing an output voltage of a voltage regulator based on monitoring of the output voltage according to some implementations.

FIG. 20 is a diagram illustrating an electronic device according to some implementations.

FIG. 21 is a diagram illustrating some implementations of a ripple monitor included in the electronic device of FIG. 20.

FIG. 22 is a timing diagram illustrating an operation of the electronic device of FIG. 20.

FIG. 23 is a block diagram illustrating some implementations of a temperature measurement circuit included in an electronic device according to some implementations.

FIG. 24 is a circuit diagram illustrating some implementations of a temperature detector included in the temperature measurement circuit of FIG. 23.

FIGS. 25 and 26 are diagrams illustrating a voltage regulator according to some implementations.

FIG. 27 is a diagram illustrating an electronic device according to some implementations.

### DETAILED DESCRIPTION

Various implementations will be described more fully hereinafter with reference to the accompanying drawings, in which some implementations are shown. In the drawings, like numerals refer to like elements throughout. The repeated descriptions may be omitted.

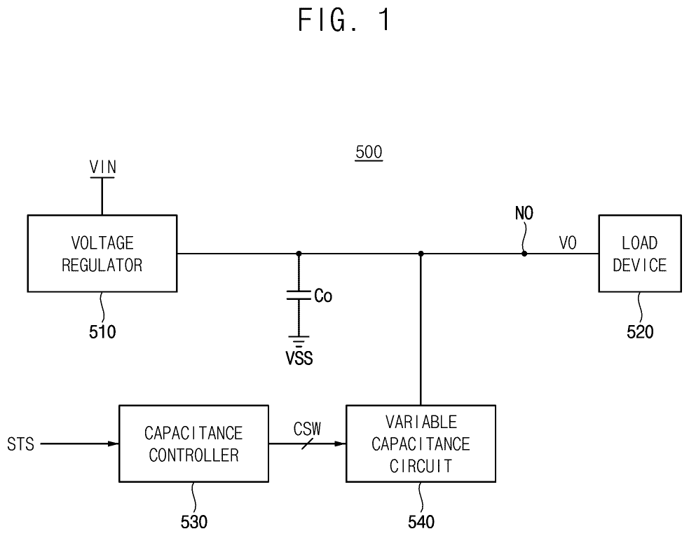

FIG. 1 is a block diagram illustrating an electronic device according to some implementations.

Referring to FIG. 1, an electronic device 500 includes a voltage regulator 510, a load device 520, an output capacitor Co, a capacitance controller 530, and a variable capacitance circuit 540.

The voltage regulator 510 may convert an input voltage VIN to generate an output voltage VO through an output node NO. The voltage regulator 510 may include various types of a DC-DC converter, such as a buck converter, a boost converter, a buck-boost converter, a switching converter, and the like.

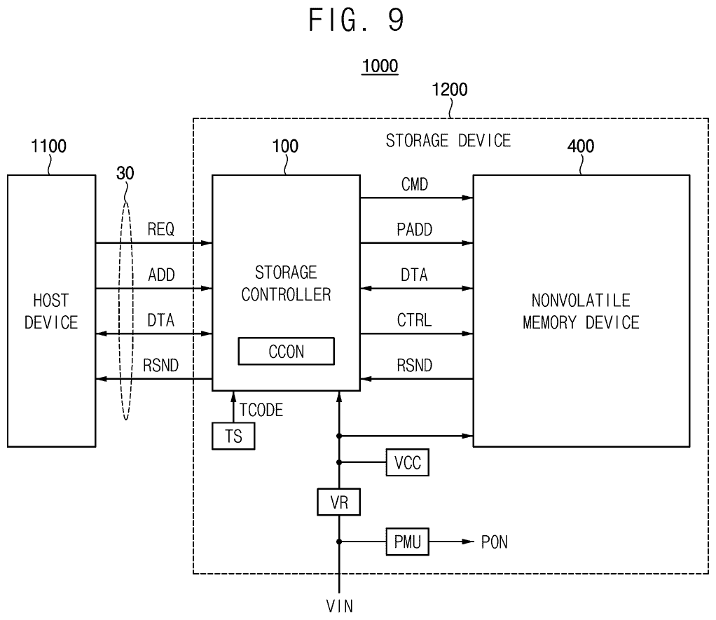

The load device 520 may operate based on the output voltage VO as a power supply voltage. The load device 520 may have various configurations according to the function of the electronic device 500. In some implementations, as will be described below with reference to FIG. 9, the electronic device 500 may be a storage device, in which case the load device 520 may correspond to a storage controller and a nonvolatile memory device.

The output capacitor Co is connected to the output node NO and has a fixed capacitance.

The capacitance controller 530 may generate a plurality of capacitance control signals CSW based on a state signal STS indicating an operation state of the electronic device 500. The variable capacitance circuit 540 is connected to the output node NO and has a capacitance that changes based on the plurality of capacitance control signals CSW.

In some implementations, as will be described below with reference to FIGS. 6 through 8 and FIGS. 14 through 18, the state signal STS may be a signal provided without actually measuring the variation of the output voltage VO. The variation of the output voltage VO may be predicted without actually measuring the variation of the output voltage VO based on a temperature code indicating an operation temperature or the like.

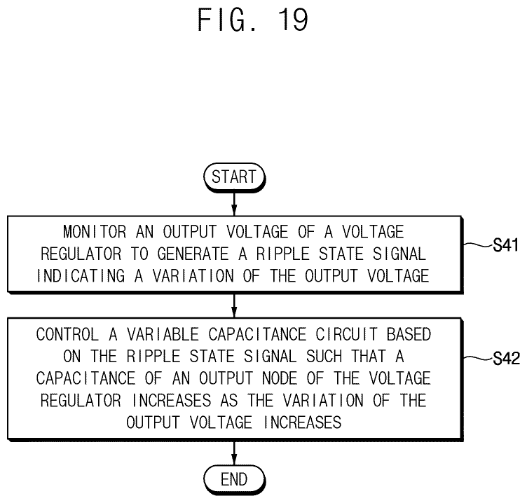

In some implementations, as will be described below with reference to FIGS. 19 through 22, the state signal STS may be a signal provided by actually measuring the variation of the output voltage VO.

While a larger fixed capacitance of the output capacitor Co may improve stability by reducing fluctuations or ripples in the output voltage VO, setting the capacitance of the output capacitor Co larger than necessary may result in unnecessary power consumption. Furthermore, setting a large fixed capacitance of the output capacitor Co may cause a sudden current to be generated during the power-on process of the electronic device 500, which may result in malfunction of an overcurrent protection circuit included in the electronic device 500.

According to some implementations, the variable capacitance circuit 540 may be utilized to change the capacitance of the output node NO of the voltage regulator 510 according to the operation state of the electronic device 540, thereby preventing malfunction of the electronic device 500 and improving the performance of the electronic device 500.

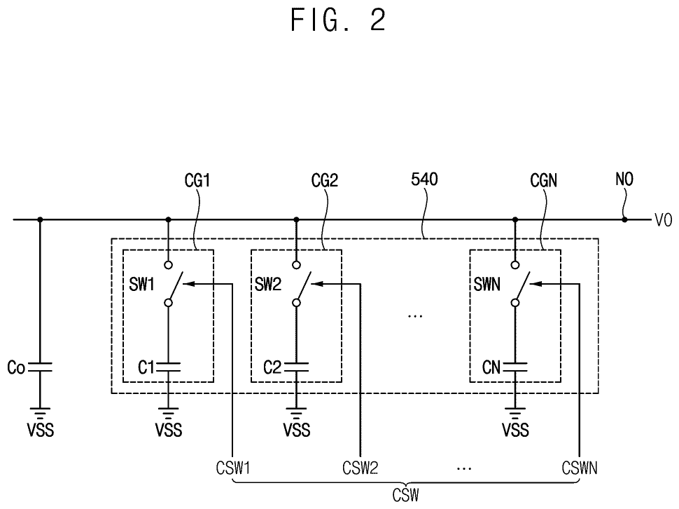

FIG. 2 is a diagram illustrating some implementations of a variable capacitance circuit included in the electronic device of FIG. 1.

Referring to FIG. 2, a variable capacitance circuit 540 may include a plurality of capacitor groups, such as first through N-th capacitor groups CG1˜CGN.

The plurality of capacitor groups CG1˜CGN receive a plurality of capacitance control signals CSW, such as first through N-th capacitance control signals CSW1˜CSWN, that is, the i-th capacitor group receives the i-th capacitance control signal CSWi (i=1˜N), and are connected in parallel to the output node NO.

The capacitor group CGi may include a respective capacitor Ci and a respective switch SWi.

Each switch SWi may electrically connect the respective capacitor Ci to the output node NO in response to activation of the respective capacitance control signal CSWi. The capacitors C1-CN included in the plurality of capacitor groups CG1-CGN may have the same capacitance or may have different capacitances.

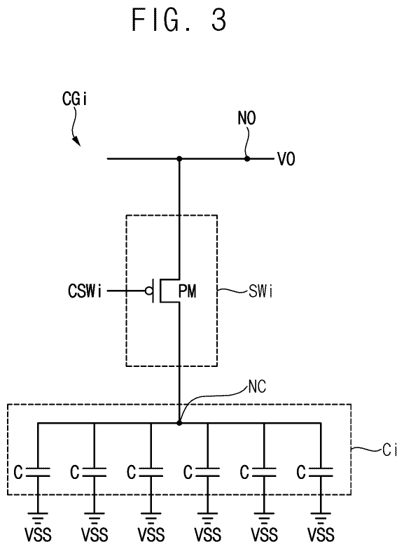

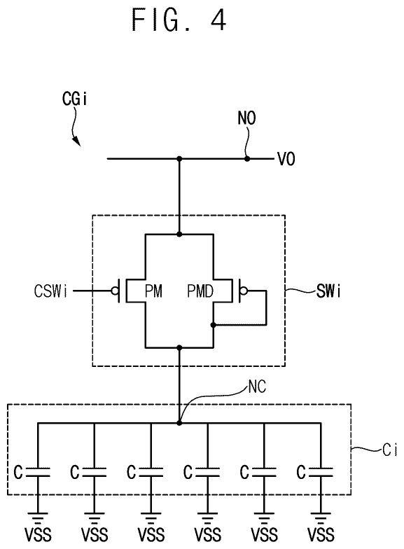

FIGS. 3 and 4 are diagrams illustrating some implementations of capacitance groups included in the variable capacitance circuit of FIG. 2.

Referring to FIG. 3, the switch SWi included in the capacitor group CGi is connected between the output node NO and a capacitor node NC, and the capacitor Ci included in the capacitor group CGi is connected between the capacitor node NC and a ground voltage VSS.

The capacitor group CGi may be implemented including a transistor PM. In some implementations, as shown in FIG. 3, the transistors PM may be implemented as PMOS transistors, but some implementations are not limited thereto.

The capacitor Ci may include a plurality of capacitors C connected in parallel between the capacitor node NC and the ground voltage VSS. In some implementations, the capacitor Ci may be implemented by connecting in parallel MOS capacitors formed as a portion of an integrated circuit. In some implementations, the capacitor Ci may be implemented in the form of an independent component, such as a multi-layer ceramic capacitor (MLCC).

Referring to FIG. 4, the switch SWi included in the capacitor group CGi is connected between the output node NO and the capacitor node NC, and the capacitor Ci included in the capacitor group CGi is connected between the capacitor node NC and the ground voltage VSS.

The capacitor group CGi includes a first transistor PM and a second transistor PMD. In some implementations, as shown in FIG. 4, the first transistor PM and the second transistor PMD may be implemented as PMOS transistors, but some implementations are not limited thereto.

The first transistor PM may be connected between the output node NO and the capacitor Ci and have a gate electrode receiving the respective capacitance control signal CSWi.

The second transistor PMD may be connected in parallel with the first transistor PM between the output node NO and the capacitor Ci, and have a gate electrode and a drain electrode that are connected electrically to each other. In other words, the second transistor PMD may be implemented as a diode-coupled transistor.

The capacitor Ci may include a plurality of capacitors C connected in parallel between the capacitor node NC and the ground voltage VSS.

The diode-coupled second transistor PMD may be utilized to precharge the voltage across the capacitor node NC to a voltage equal to the output voltage VO minus the threshold voltage of the second transistor PMD until the first transistor PM is turned on. This precharge of the capacitor node NC allows the capacitance of the output node NO to be quickly increased when the capacitance control signal CSWi is activated.

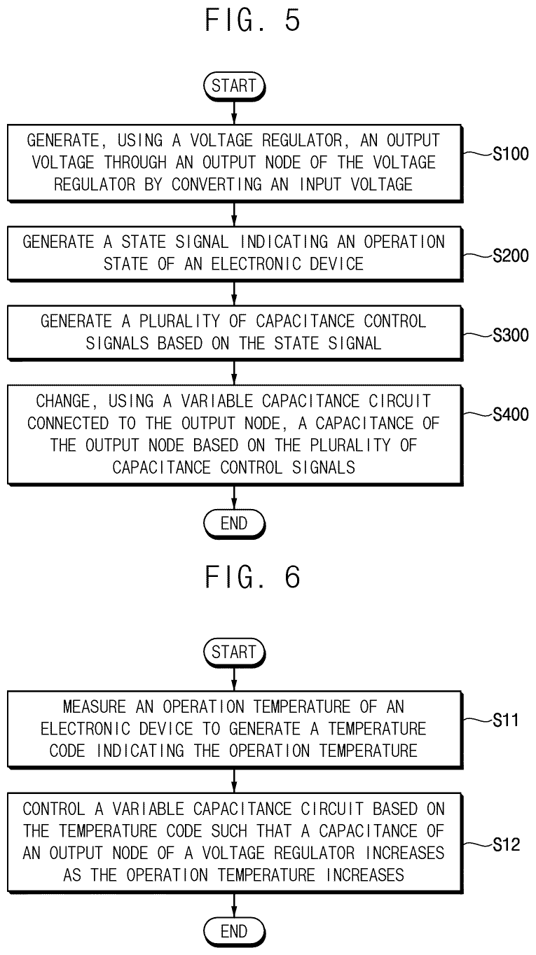

FIG. 5 is a flowchart illustrating a method of stabilizing an output voltage of a voltage regulator according to some implementations.

Referring to FIGS. 1 and 5, the voltage regulator 510 may be utilized to convert the input voltage VIN to generate the output voltage VO through the output node NO of the voltage regulator 510 (S100).

The state signal STS indicating the operation state of the electronic device 500 may be generated (S200). The state signal STS may include information for predicting a change in the output voltage VO or may be a signal provided by actually measuring a change in the output voltage VO.

The capacitance controller 530 may generate the plurality of capacitance control signals CSW based on the state signal STS (S300).

Using the variable capacitance circuit 540 connected to the output node NO, the capacitance of the output node NO may be changed (S400) based on the plurality of capacitance control signals CSW.

Hereinafter, some implementations of controlling the capacitance of the output node NO in anticipation of fluctuations in the output voltage VO will be described with reference to FIGS. 6 through 16B.

FIG. 6 is a flowchart illustrating a method of stabilizing an output voltage of a voltage regulator based on an operation temperature of an electronic device according to some implementations.

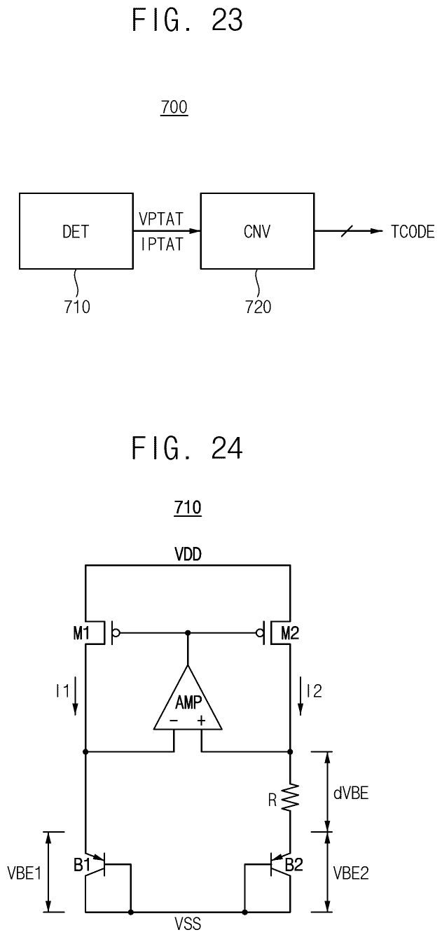

Referring to FIG. 6, an operation temperature of the electronic device may be monitored to generate a temperature code indicating the operation temperature (S11). Information regarding the operation temperature may be provided using various temperature measurement circuits. In some implementations, as will be described below with reference to FIGS. 23 and 24, the operation temperature may be provided using an on-chip temperature sensor formed on a semiconductor die of the electronic device 500.

The capacitance controller 530 of FIG. 1 may control the variable capacitance circuit 540 based on the temperature code, such that the capacitance of the output node NO increases as the operation temperature increases (S12).

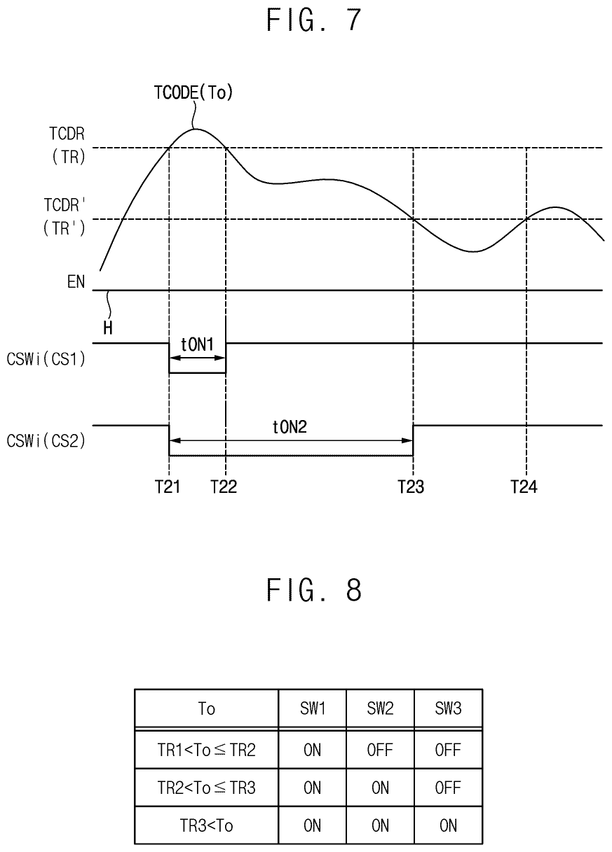

FIG. 7 is a flowchart illustrating some implementations of capacitance control signals according to the method of FIG. 6.

Referring to FIGS. 1 and 7, the capacitance controller 530 may generate the capacitance control signal CSWi based on the state signal STS indicating the operation temperature To of the electronic device 500.

In some implementations, as illustrated as a first case CS1 in FIG. 7, the capacitance controller 530 may activate the capacitance control signal CSWi to a logic low level at a time point (e.g., T21) when the operation temperature To increases to be higher than a reference temperature TR, and deactivate the capacitance control signal CSWi to a logic high level at a time point (e.g., T22) when the operation temperature To decreases to be lower than the reference temperature TR. In this case, the activation time interval tON1 of the capacitance control signal CSWi may vary depending on the change in the operation temperature To. During the activation time interval tON1, the capacitance of the output node NO may increase by the capacitance of the capacitor Ci.

In some implementations, as illustrated as a second case CS2 in FIG. 7, the capacitance controller 530 may activate the capacitance control signal CSWi to a logic low level at a time point (e.g., T21) when the operation temperature To increases to be higher than a first reference temperature TR, and deactivate the capacitance control signal CSWi to a logic high level at a time point (e.g., T23) when the operation temperature To decreases to be lower than a second reference temperature TR′ that is lower than the first reference temperature.

In FIG. 7, TCDR represents the value of the temperature code TCODE corresponding to the first reference temperature TR, and TCDR′ represents the value of the temperature code TCODE corresponding to the second reference temperature TR′. The above-mentioned state signal STS corresponds to the temperature code TCODE indicating the operation temperature To of the electronic device.

The activation time interval tON2 of the capacitance control signal CSWi may vary depending on the change in the operation temperature To. As described above, the activation time interval tON2 of the capacitance control signal CSWi corresponds to the turn-on time of the switch SWi in FIGS. 3 and 4, and therefore, the capacitance of the output node NO may increase by the capacitance of the capacitor Ci during the activation time interval tON2.

In some implementations, as the second case CS2, even if the operation temperature To exceeds the second reference temperature TR′ at time T24, the capacitance controller 530 may not activate the capacitance control signal CSWi.

In this way, a hysteresis method may be applied such that the second reference temperature TR′, which is a reference for deactivating the capacitance control signal CSWi, is set lower than the first reference temperature TR, which is a reference for activating the capacitance control signal CSWi. By applying the hysteresis method, frequent changes in the capacitance of the output node may be prevented, thereby stabilizing the operation and efficiently improving the performance of the electronic device.

FIG. 8 is a diagram for describing a method of stabilizing an output voltage of a voltage regulator based on an operation temperature of an electronic device according to some implementations.

Referring to FIG. 8, the operation temperature To may be divided into a plurality of operation temperature intervals. For example, as illustrated in FIG. 8, the operation temperature To may be divided into a first temperature interval greater than a first reference temperature TR1 and less than or equal to a second reference temperature TR2, a second temperature interval greater than the second reference temperature TR2 and less than or equal to a third reference temperature TR3, and a third temperature interval greater than the third reference temperature TR3.

For example, in the first temperature interval where the operation temperature To is greater than the first reference temperature TR1 and less than the second reference temperature TR2, the first switch SWi included in the first capacitor group CS1 may be turned on to electrically connect the first capacitor C1 to the output node NO. In the second temperature interval where the operation temperature To is greater than the second reference temperature TR2 and less than the third reference temperature TR3, the first switch SW1 included in the first capacitor group CS1 and the second switch SW2 included in the second capacitor group CG2 may be turned on to electrically connect the first capacitor C1 and the second capacitor C2 to the output node NO. In the third temperature interval where the operation temperature To is greater than the third reference temperature TR2, the first switch SW1 included in the first capacitor group CS1, the second switch SW2 included in the second capacitor group CG2, and the third switch SW3 included in the second capacitor group CG3 may be turned on to electrically connect the first capacitor C1, the second capacitor C2, and the third capacitor C3 to the output node NO.

In this way, the capacitance controller 530 of FIG. 1 may sequentially increase the number of capacitance control signals CSW of the plurality of capacitance control signals that are activated per operation temperature interval based on the temperature code TCODE, such that the number of capacitor groups electrically connected to the output node NO increases sequentially as the operation temperature To increases.

FIG. 9 is a block diagram illustrating a storage system according to some implementations.

Referring to FIG. 9, a storage system 1000 includes a host device 1100, a storage device 1200, and a link 30 connecting the host device 1100 and the storage device 1200. The storage device 1200 includes a storage controller 100 and a nonvolatile memory device 400. For example, the storage device 1200 may be a solid state drive (SSD), an embedded multimedia card (eMMC), or a universal flash storage (UFS) device. In some implementations, the link 30 may be a Peripheral Component Interconnect Express (PCIe) link.

The host device 1100 may be a data processing device capable of processing data, such as a central processing unit (CPU), a microprocessor, an application processor, and the like. The storage device 1200 may be embedded in an electronic device together with the host device 1100, and may be electrically connected to the electronic device including the host device 1100 in a detachable manner.

The host device 1100 may transmit a data operation request, that is, a request REQ and an address ADD, to the storage controller 100, and may exchange data DTA with the storage controller 100. The storage controller 100 may transmit a response RSND responding to the data operation request REQ to the host device 1100. The data operation request REQ may include a data read request, a data write request, or a data erase request.

The storage controller 100 may control the nonvolatile memory device 400 in response to the request REQ from the host device 1100. By providing the nonvolatile memory device 400 with a physical address PADD mapped to the logical address ADD, a command CMD, and a control signal CTRL to perform the read operations or the write operations on the nonvolatile memory device 400 The write operation may be referred to as a program operation. For example, the storage controller 100 may perform a flash translation layer (FTL) operation to convert the logical address ADD transmitted from the host device 1100 into the physical address PADD of the nonvolatile memory device 400.

For example, the storage controller 100 reads out the data DTA stored in the nonvolatile memory device 400 in response to the data read request received from the host device 1100, or store the data DTA received from the host device 1100 in the non-volatile memory device 400 in response to the data write request received from the host device 1100. Additionally, the nonvolatile memory device 400 may be controlled to erase data DTA stored in the nonvolatile memory device 400 in response to the data erase request received from the host device 1100. The nonvolatile memory device 400 may transmit the response RSND responding to the command CMD to the storage controller 100.

The nonvolatile memory device 400 may be comprised of one or more nonvolatile memories (NVM) such as flash memory, magnetic RAM (MRAM), ferroelectric RAM (FeRAM), phase change RAM (PRAM), and resistive RAM (ReRAM). The nonvolatile memory device 400 may be connected to the storage controller 100 through a plurality of channels. Hereinafter, for convenience of descriptions, the nonvolatile memory device 400 may be described as an example of a NAND flash memory device.

According to some implementations, the storage device 1200 further includes a temperature measurement circuit TS, a voltage regulator VR, a variable capacitance circuit VCC, and a power management circuit PMU.

The temperature measurement circuit TS may measure the operation temperature of the storage device 1200 and generate a temperature code TCODE indicating the operation temperature of the storage device 1200. The temperature measurement circuit TS provides an operation temperature in a power-on state and may be disabled in a power-off state to save power consumption.

The power management circuit PMU may monitor the input voltage VIN to generate a power-on signal PON that indicates the start of the power-on sequence of the storage device 1200.

As described above, the voltage regulator VR may convert the input voltage VIN to generate the output voltage VO through the output node NO. The variable capacitance circuit VCC may be connected to the output node NO and have a capacitance that changes based on the plurality of capacitance control signals.

The storage controller 100 and the nonvolatile memory device 400 may operate based on the output voltage VO as the power supply voltage. In other words, the storage controller 100 and the nonvolatile memory device 400 may correspond to the load device 520 of FIG. 1.

The storage controller 100 includes the capacitance controller CCON. FIG. 9 shows some implementations in which the capacitance controller CCON is included in the storage controller 100. However, depending on implementations, the capacitance controller CCON may be implemented as a separate component distinct from the storage controller 100. The capacitance controller CCON may be implemented in hardware, software, or a combination of hardware and software.

In some implementations, as described above with reference to FIGS. 6 through 8, the capacitance controller CCON may control variable capacitance circuit VCC based on the temperature code TCODE such that the capacitance of the output node NO increases as the operation temperature of the storage device 1200 increases.

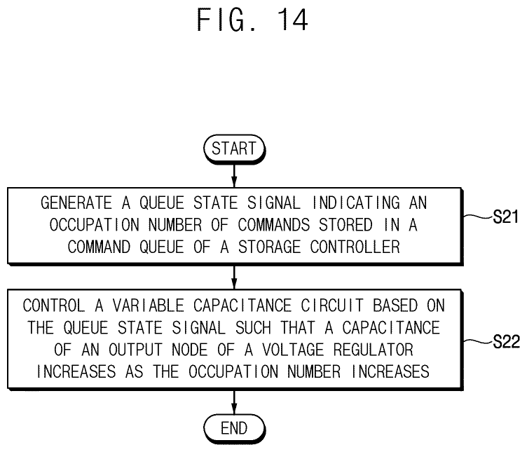

In some implementations, as will be described below with reference to FIGS. 14 through 16B, the capacitance controller CCON may control the variable capacitance circuit VCC based on a queue state signal such that the capacitance of the output node NO increases as the occupation number of commands stored in the command queue increases.

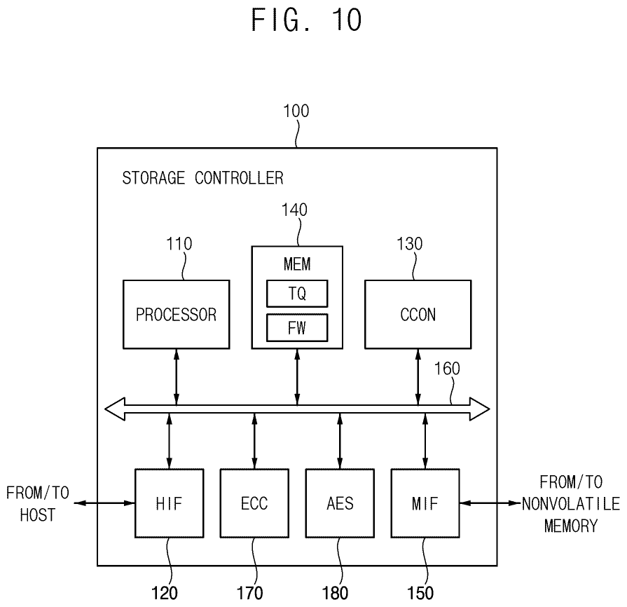

FIG. 10 is a block diagram illustrating a storage controller according to some implementations.

Referring to FIG. 10, a storage controller 100 includes a processor 110, a memory (MEM) 140, a capacitance controller (CCON) 130, a host interface (HIF) 120, an error correction code (ECC) engine 170, a memory interface (MIF) 150, an advanced encryption standard (AES) engine 180, and an internal bus system 160 that connects the components in the storage controller 100.

The processor 110 may control an operation of the storage controller 100 in response to commands received via the host interface 120 from a host device (e.g., the host device 1100 in FIG. 9). For example, the processor 110 may control an operation of a storage device (e.g., the storage device 1200 in FIG. 9), and may control respective components by employing firmware for operating the storage device.

The memory 140 may store instructions and data executed and processed by the processor 110. For example, the buffer memory 140 may be implemented with a volatile memory, such as a DRAM, a SRAM, a cache memory, or the like.

The ECC engine 170 for error correction may perform coded modulation using a Bose-Chaudhuri-Hocquenghem (BCH) code, a low density parity check (LDPC) code, a turbo code, a Reed-Solomon code, a convolution code, a recursive systematic code (RSC), a trellis-coded modulation (TCM), a block coded modulation (BCM), and/or the like. In some implementations, the ECC engine 170 may perform ECC encoding and ECC decoding using above-described codes or other error correction codes.

The host interface 120 may provide physical connections between the host device 1100 and the storage device 1200. The host interface 120 may provide an interface that corresponds to a bus format of the host device 1100 for communication between the host device 1100 and the storage device 1200. In some implementations, the bus format of the host device 1100 may be a small computer system interface (SCSI) or a serial attached SCSI (SAS) interface. In other implementations, the bus format of the host device may be a USB, a peripheral component interconnect (PCI) express (PCIe), an advanced technology attachment (ATA), a parallel ATA (PATA), a SATA, a nonvolatile memory (NVM) express (NVMe), or other format.

The memory interface 150 may exchange data with a nonvolatile memory device (e.g., the nonvolatile memory device 400 in FIG. 9). The memory interface 150 may transfer data to the nonvolatile memory device 400, and/or may receive data read from the nonvolatile memory device 400. In some implementations, the memory interface 150 may be connected to the nonvolatile memory device 400 via one channel. In other implementations, the memory interface 150 may be connected to the nonvolatile memory device 400 via two or more channels. The memory interface 150 may be configured to comply with a standard protocol, such as Toggle or open NAND flash interface (ONFI).

The AES engine 180 may perform at least one of an encryption operation or a decryption operation on data input to the storage controller 100 using a symmetric-key algorithm. The AES engine 180 may include an encryption module and a decryption module. For example, the encryption module and the decryption module may be implemented as separate modules. In another example, one module capable of performing both encryption and decryption operations may be implemented in the AES engine 180.

As described above, the capacitance controller CCON may generate a plurality of capacitance control signals based on a state signal indicating the operation state of the storage device. The capacitance controller CCON may be implemented as separate hardware, or may be implemented in the form of firmware stored in the memory 140 and executed by the processor 110.

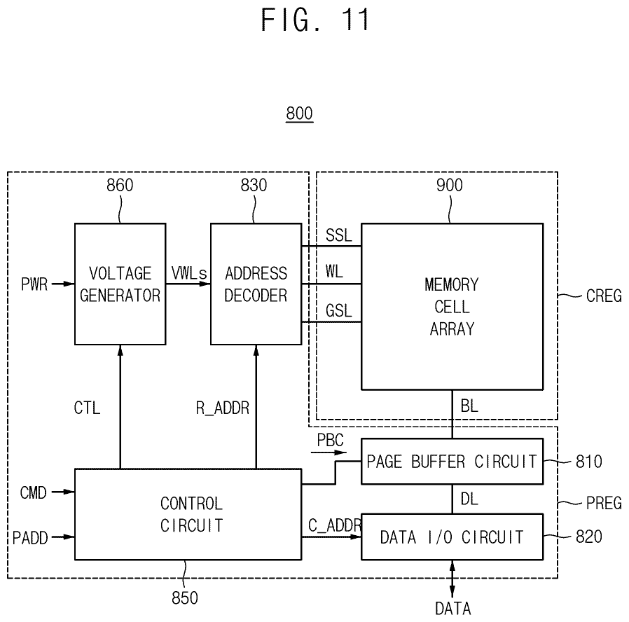

FIG. 11 is a block diagram illustrating a nonvolatile memory device according to some implementations.

Referring to FIG. 11, a nonvolatile memory device 800 includes a memory cell array 900, a page buffer circuit 810, a data input/output (I//O) circuit 820, an address decoder 830, a control circuit 850, and a voltage generator 860. In some implementations, the nonvolatile memory device 800 may have a cell over periphery (COP) structure in which a memory cell array is arranged over peripheral circuits. In this case, the memory cell array 900 may be formed in a cell region CREG, and the page buffer circuit 810, the data I/O circuit 820, the address decoder 830, the control circuit 850, and the voltage generator 860 may be formed in a peripheral region PREG.

The memory cell array 900 may be coupled to the address decoder 830 through string selection lines SSL, wordlines WL, and ground selection lines GSL. The memory cell array 900 may be coupled to the page buffer circuit 810 through bitlines BL. The memory cell array 900 may include memory cells coupled to the wordlines WL and the bitlines BL. In some implementations, the memory cell array 900 may be a three-dimensional memory cell array, which may be formed on a substrate in a three-dimensional structure (or a vertical structure). In this case, the memory cell array 900 may include cell strings (e.g., NAND strings) that are vertically oriented such that at least one memory cell is located over another memory cell.

The control circuit 850 may receive a command signal CMD and an address signal PADD from a memory controller, and may control erase, program, and read operations of the nonvolatile memory device 800 in response to (or based on) at least one of the command signal CMD and the address signal PADD. The erase operation may include performing a sequence of erase loops, and the program operation may include performing a sequence of program loops. Each program loop may include a program operation and a program verification operation. Each erase loop may include an erase operation and an erase verification operation. The read operation may include a normal read operation and data recover read operation.

In some implementations, the control circuit 850 may generate a control signals CTL used to control the operation of the voltage generator 860, and may generate a page buffer control signal PBC for controlling the page buffer circuit 810, based on the command signal CMD, and may generate a row address R_ADDR and a column address C_ADDR based on the address signal PADD. The control circuit 850 may provide the row address R_ADDR to the address decoder 830, and may provide the column address C_ADDR to the data I/O circuit 820.

The address decoder 830 may be coupled to the memory cell array 900 through the string selection lines SSL, the wordlines WL, and the ground selection lines GSL.

During the program operation or the read operation, the address decoder 830 may determine (or select) one of the wordlines WL as a selected wordline, and may determine or designate the remaining wordlines WL other than the selected wordline as unselected wordlines based on the row address R_ADDR.

In addition, during the program operation or the read operation, the address decoder 830 may determine one of the string selection lines SSL as a selected string selection line and determine or designate the remaining string selection lines SSL other than the selected string selection line as unselected string selection lines based on the row address R_ADDR. The aforementioned selected memory cells correspond to the memory cells connected to the selected wordline and the selected string selection line.

The voltage generator 860 may generate wordline voltages VWL, which are used for the operation of the memory cell array 900 of the nonvolatile memory device 800, based on the control signals CTL. The voltage generator 860 may receive the power PWR from the memory controller. The wordline voltages VWL may be applied to the wordlines WL through the address decoder 830.

In some implementations, during the erase operation, the voltage generator 860 may apply an erase voltage to a well and/or a common source line of a memory block, and may apply an erase permission voltage (e.g., a ground voltage) to all of the wordlines of the memory block or a portion of the wordlines based on an erase address. During the erase verification operation, the voltage generator 860 may apply an erase verification voltage simultaneously to all of the wordlines of the memory block or sequentially (e.g., one by one) to the wordlines.

In some implementations, during the program operation, the voltage generator 860 may apply a program voltage to the selected wordline, and may apply a program pass voltage to the unselected wordlines. During the program verification operation, the voltage generator 860 may apply a program verification voltage to the first wordline, and may apply a verification pass voltage to the unselected wordlines.

During the normal read operation, the voltage generator 860 may apply a read voltage to the selected wordline, and may apply a read pass voltage to the unselected wordlines. During the data recover read operation, the voltage generator 860 may apply the read voltage to a wordline adjacent to the selected wordline, and may apply a recover read voltage to the selected wordline.

The page buffer circuit 810 may be coupled to the memory cell array 900 through the bitlines BL. The page buffer circuit 810 may include multiple buffers. In some implementations, each buffer may be connected to only a single bitline. In some implementations, each buffer may be connected to two or more bitlines. The page buffer circuit 810 may temporarily store data to be programmed in a selected page or data read out from the selected page of the memory cell array 900.

The data I/O circuit 820 may be coupled to the page buffer circuit 810 through data lines DL. During the program operation, the data I/O circuit 820 may receive program data DATA received from the memory controller and provide the program data DATA to the page buffer circuit 810 based on the column address C_ADDR received from the control circuit 850. During the read operation, the data I/O circuit 820 may provide read data DATA, read from the memory cell array 900 and stored in the page buffer circuit 810, to the memory controller based on the column address C_ADDR received from the control circuit 850.

The page buffer circuit 810 and the data I/O circuit 820 may read data from a first area of the memory cell array 900, and may write this read data to a second area of the memory cell array 900 (e.g., without transmitting the data to a source external to the nonvolatile memory device 800, such as to the memory controller). Thus, the page buffer circuit 810 and the data I/O circuit 820 may perform a copy-back operation.

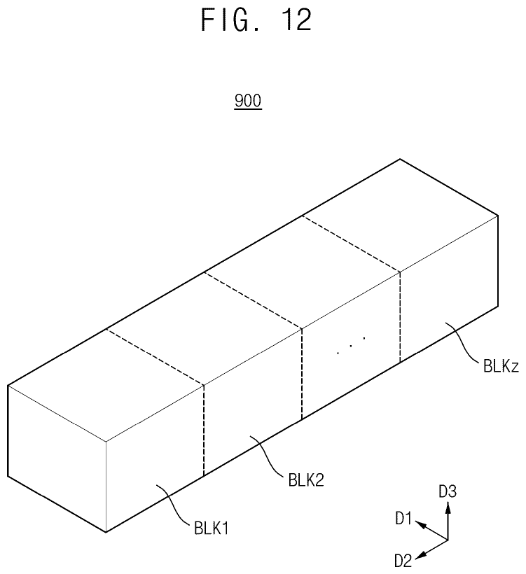

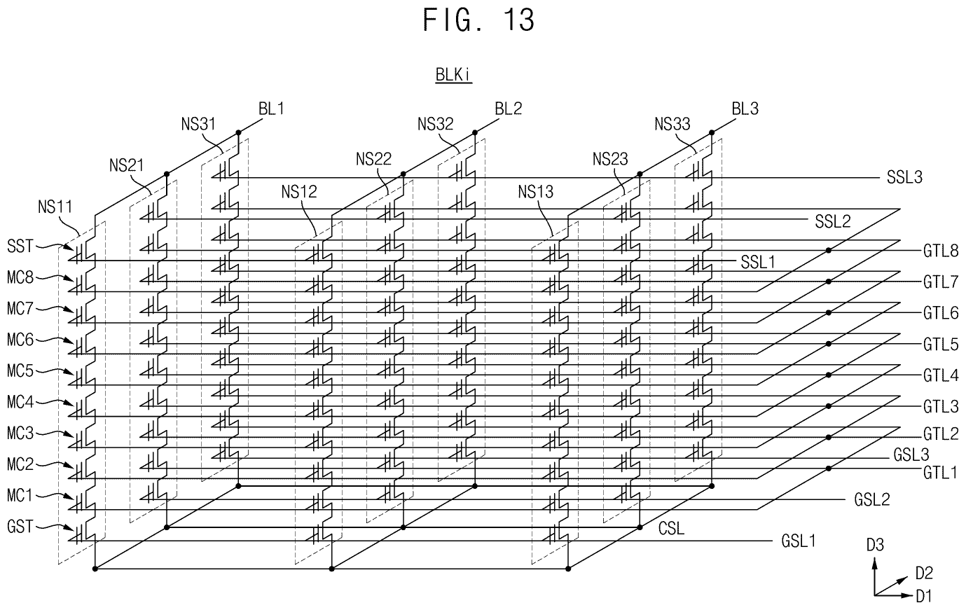

FIG. 12 is a block diagram illustrating a memory cell array included in the nonvolatile memory device of FIG. 11, and FIG. 13 is a circuit diagram illustrating an equivalent circuit of a memory block included in the memory cell array of FIG. 12.

Referring to FIG. 12, the memory cell array 900 includes memory blocks BLK1 to BLKz. In some implementations, the memory blocks BLK1 to BLKz may be selected by the address decoder 830 of FIG. 6. For example, the address decoder 830 may select a particular memory block BLK corresponding to a block address among the memory blocks BLK1 to BLKz.

A memory block BLKi (i being an integer from 1 to z) of FIG. 13 may be formed on a substrate in a three-dimensional structure (or a vertical structure). For example, NAND strings or cell strings included in the memory block BLKi may be formed and stacked in a vertical direction D3 perpendicular to an upper surface of a substrate.

Referring to FIG. 13, the memory block BLKi includes NAND strings NS11 to NS33 coupled between bitlines BL1, BL2, and BL3 and a common source line CSL. Each of the NAND strings NS11 to NS33 includes a string selection transistor SST, a memory cells MC1 to MC8, and a ground selection transistor GST. In FIG. 13, each of the NAND strings NS11 to NS33 is illustrated to include eight memory cells MC1 to MC8. However, some implementations are not limited thereto, and each of the NAND strings NS11 to NS33 may include various numbers of memory cells.

Each string selection transistor SST may be connected to a corresponding string selection line (one of SSL1 to SSL3). The memory cells MC1 to MC8 may be connected to corresponding gate lines GTL1 to GTL8, respectively. The gate lines GTL1 to GTL8 may be wordlines, and some of the gate lines GTL1 to GTL8 may be dummy wordlines. Each ground selection transistor GST may be connected to a corresponding ground selection line (one of GSL1 to GSL3). Each string selection transistor SST may be connected to a corresponding bitline (e.g., one of BL1, BL2, and BL3), and each ground selection transistor GST may be connected to the common source line CSL.

Wordlines (e.g., WL1) having the same or similar height may be commonly connected, and the ground selection lines GSL1 to GSL3 and the string selection lines SSL1 to SSL3 may be separated. In FIG. 13, the memory block BLKi is illustrated as being coupled to eight gate lines GTL1 to GTL8 and three bitlines BL1 to BL3. However, some implementations are not limited thereto, and each memory block in the memory cell array 900 may be coupled to various numbers of wordlines and various numbers of bitlines.

FIG. 14 is a flowchart illustrating a method of stabilizing an output voltage of a voltage regulator based on an occupation state of a command queue included in a storage device according to some implementations.

Referring to FIGS. 9, 10, and 14, a queue state signal indicating an occupation number of commands stored in the command queue of the storage controller 100 may be generated (S21).

The capacitance controller 130 may control the variable capacitance circuit VCC based on the queue state signal, such that the capacitance of the output node NO of the voltage regulator VR increases as the occupation number increases (S22).

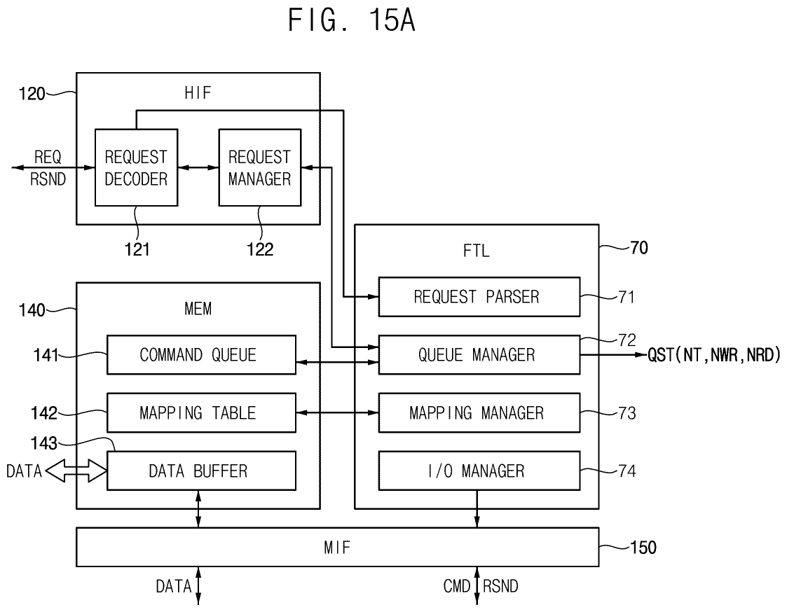

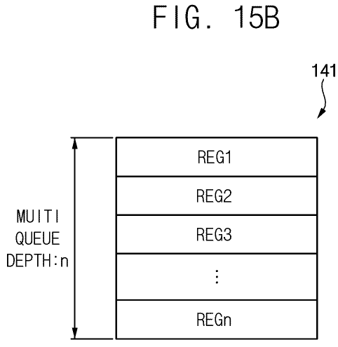

FIGS. 15A and 15B are diagrams illustrating an example configuration of a storage controller included in a storage device according to some implementations.

FIG. 15A illustrates example components of the storage controller 100 of FIG. 10, including the host interface 120, the memory 140, and the memory interface 150, along with a flash translation layer (hereinafter referred to as “FTL”) 70 performed by the processor 110.

Referring to FIG. 15A, the host interface 120 includes a command decoder 121 and a request manager 122. The command decoder 121 may decode a request REQ received from the host device, and the request manager 122 may pass the decoded command to the command parser 71 of the FTL 70.

The memory 140 includes a data buffer 1433, and the command queue 141 and the mapping table 142 may be loaded to the memory 140. For example, one portion of memory 140 may act as a data buffer 143, while the command queue 141 and the mapping table 142 may be loaded to another portion of the memory 140.

The mapping table 142 may store mapping information for logical addresses received from the host device and physical addresses of the nonvolatile memory. In some implementations, the nonvolatile memory may store a plurality of mapping tables, and when power is applied to the storage device, some of the plurality of mapping tables stored in the nonvolatile memory may be loaded into the memory 140 of the storage controller.

The data buffer 143 may temporarily store received data (write data or read data) and may receive write data from a host device or transmit read data to the host 200 under the control of the host interface 120.

The FTL 70 includes a request parser 71, a queue manager 72, a mapping manager 73, and an input/output (I/O) manager 74. In some implementations, the FTL 70 may be loaded into memory 140 and executed by a processor (e.g., 110 in FIG. 10).

The request parser 71 may receive the request REQ from the request decoder 121 and may check variables in the received request REQ.

The request REQ may include a plurality of bits, for example, a start bit, a transmission bit, a request index, a cyclic redundancy check (CRC), an end bit, and the like.

The start bit may be a bit that indicates the start of the REQ and may be fixed to zero, for example. The transmission bit may be a bit indicating the entity that generated the REQ. The request index may be a plurality of bits indicating a type of request, which may indicate that the request is a specific request among a plurality of requests that the storage device may perform. For example, the request index may indicate that the incoming request is a write request, a read request, or the like. Thus, the storage controller may recognize which request is incoming based on the request index and may perform actions based on the request index.

The CRC is for detecting errors that may occur in the transmission of the request REQ, and the end bit is a bit that indicates the end of the request REQ and may be fixed to 1, for example.

The request parser 71 may extract address, data size, mode information, and the like from the request REQ and store the extracted information in the command queue 141 as command information.

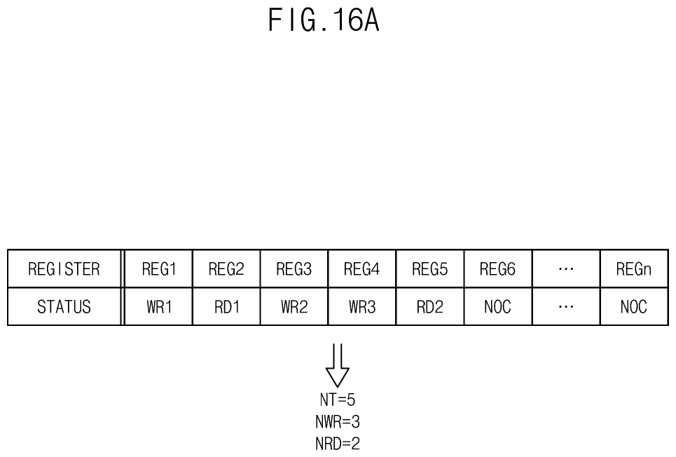

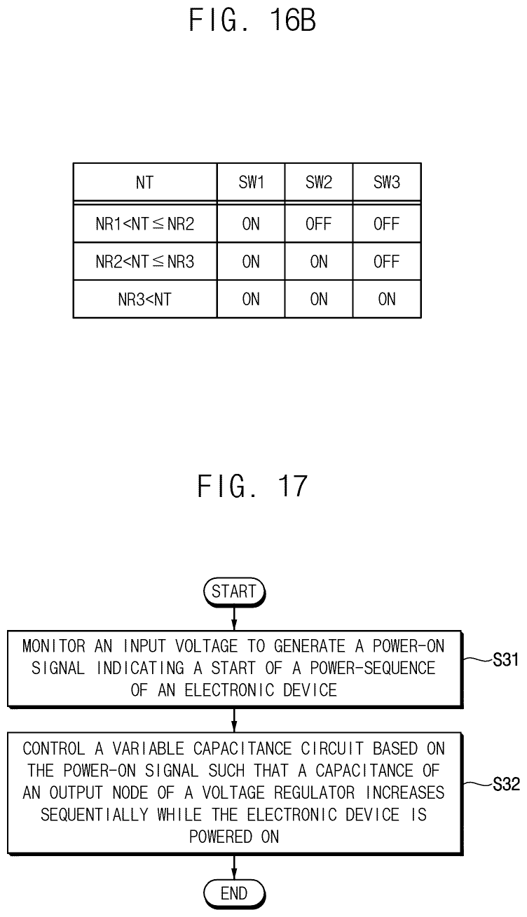

The queue manager 72 may select one of the plurality of commands queued in the command queue 141 and determine whether the selected command is ready. If the queue manager 72 determines the selected command to be ready, the queue manager 72 may update the state register as will be described below with reference to FIG. 16A. According to some implementations, the queue manager 72 may generate a queue state signal QST indicating the occupation number of commands that are stored in the command queue 141. For example, the queue state signal QST may include the total number NT of commands stored in the command queue 141, the number NWR of write commands stored in the command queue 141, the number NRD of read commands stored in the command queue 141, or the like.

The mapping manager 73 may manage the mapping table 142. For example, the mapping manager 73 may update the mapping table 142 when a physical address for a logical address changes, by storing the mapping information of the physical address for the changed logical address in the mapping table 142.

In response to a write execution request, the I/O manager 74 may issue a write command to be provided to the nonvolatile memory. In addition, the I/O manager 74 may issue a read command to be provided to nonvolatile memory in response to a read execution request. At this time, the I/O manager 74 may refer to the mapping table 142 to obtain a physical address corresponding to the write command or the read command.

The memory interface 150 may provide an interface between the storage controller and nonvolatile memory, and may be implemented as a Flash Interface Layer (FIL), for example. The memory interface 150 may provide commands CMD and addresses, such as physical addresses, generated based on requests received from the host device to the nonvolatile memory device to write data to the nonvolatile memory device or read data from the nonvolatile memory device.

FIG. 15B is a block diagram illustrating a command queue in more detail, in accordance with some implementations of the present disclosure.

Referring to FIG. 15B, the command queue 141 includes first through n-th command registers REG1˜REGn, and each of the first through n-th command registers REG1˜REGn may store information on the commands. Here, the number n represents a number of command registers, and is a natural number higher than 1. The number n may be defined as a multi-queue depth, and the storage controller may receive multiple commands corresponding to the multi-queue depth n from the host and store them in the first through n command registers REG1˜REGn.

FIGS. 16A and 16B are diagrams for describing a method of stabilizing an output voltage of a voltage regulator based on an occupation state of a command queue included in a storage device according to some implementations.

FIG. 16A illustrates an example of a state register that is managed by the queue manager 72 of FIG. 15A. The state register may store occupation information for each of the first through n-th command registers REG1˜REGn of the command queue 141. In the example of FIG. 16A, the first, third, and fourth command registers REG1, REG3 and REG4 may store write commands WR1, WR2 and WR3, respectively, and the second and fifth command registers REG2 and REG5 may store read commands RD1 and RD2. NOC indicates that no commands are stored in the corresponding command registers.

In this case, the queue manager 72 of FIG. 15A may generate a queue state signal QST to indicate that the total number NT of commands stored in the command queue 141 is 5, the number NWR of write commands stored in the command queue 141 is 3, and the number NRD of read commands stored in the command queue 141 is 2.

The aforementioned state signal STS may correspond to a queue state signal QST indicating the occupation number of commands stored in the command queue of the storage controller. The capacitance controller CCON of FIG. 9 may control the variable capacitance circuit VCC based on these queue state signals QST.

As the occupation number of commands stored in the command queue 72 increases, the power consumption of the storage device 1200 may increase and the variation of the output voltage VO of the voltage regulator VR may increase. The capacitance controller CCO may control the variable capacitance circuit VCC based on the queue state signal QST such that the capacitance of the output node NO increases as the occupation number, representing the number of commands stored in the command queue 72, increases.

Referring to FIG. 16B, the occupation number (e.g., NT) of commands stored in the command queue 72 of the storage controller 110 as described above with reference to FIGS. 15A, 15B, and 16A may be divided into a plurality of occupation number intervals. For example, as illustrated in FIG. 16B, the occupation number NT may be divided into a first occupation number interval that is greater than a first reference number NR1 and less than or equal to a second reference number NR2, a second occupation number interval that is greater than a second reference number NR2 and less than or equal to a third reference number NR3, and a third occupation number interval that is greater than a third reference number NR3.

For example, in the first occupation number interval where the occupation number NT is greater than the first reference count NR1 and less than or equal to the second reference count NR2, the first switch SW1 included in the first capacitor group CS1 may be turned on to electrically connect the first capacitor C1 to the output node NO. In the second occupation number interval where the occupation number NT is greater than the second reference number NR2 and less than or equal to the third reference number NR3, the first switch SW1 included in the first capacitor group CS1 and the second switch SW2 included in the second capacitor group CG2 may be turned on to electrically connect the first capacitor C1 and the second capacitor C2 to the output node NO. In the third occupation number interval where the occupation number NT is greater than the third reference count NR2, the first switch SW1 included in the first capacitor group CS1, the second switch SW2 included in the second capacitor group CG2, and the third switch SW3 included in the second capacitor group CG3 may be turned on to electrically connect the first capacitor C1, the second capacitor C2, and the third capacitor C3 to the output node NO.

In this way, the capacitance controller CCON of FIG. 9 may sequentially increase the number of capacitance control signals CSW of the plurality of capacitance control signals that are activated per occupation number interval based on the queue state signal QST such that the number of capacitor groups electrically connected to the output node NO increases sequentially as the occupation number NT increases.

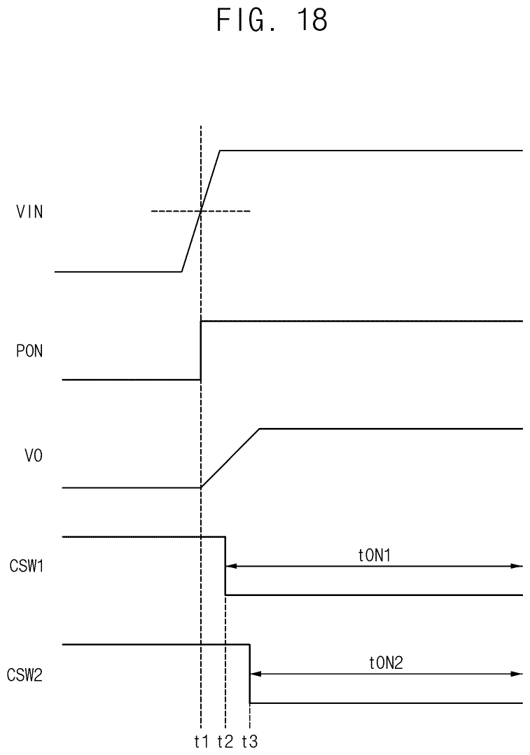

FIG. 17 is a flowchart illustrating a method of stabilizing an output voltage of a voltage regulator during a power-on sequence of an electronic device according to some implementations, and FIG. 18 is a timing diagram illustrating a method of stabilizing an output voltage of a voltage regulator during a power-on sequence of an electronic device according to some implementations.

Referring to FIGS. 17 and 18, an input voltage VIN may be monitored to generate a power-on signal PON indicating the start of a power-on sequence of the electronic device (S31). For example, the power management circuit PMU of FIG. 9 may generate the power-on signal PON that is activated to a logic high level at a time t1 when the input voltage VIN reaches a constant voltage level, as shown in FIG. 18. An electronic device, such as the storage device 1200, may initiate the power-on sequence that boots the electronic device in response to activation of such power-on signal PON.

Based on the power-on signal, the variable capacitance circuit may be controlled such that the capacitance of the output nodes is sequentially increased while the electronic device is powered on (S32).

For example, the first capacitance control signal CSW1 of the first capacitor group CG1 may be activated to a logic low level at a time t1 after a certain delay from the activation of the power-on signal PON, and a second capacitance control signal CSW2 of the second capacitor group CG2 may be activated to a logic low level at a time t2 after a certain delay. As a result, the capacitance of the output node NO of the voltage regulator may be sequentially increased during the power-on sequence.

If the fixed capacitance of the output capacitor Co is set to a large value, a sudden current may be generated during the power-on process of the electronic device, which may result in malfunction of the overcurrent protection circuit included in the electronic device. By sequentially increasing the capacitance of the output node NO of the voltage regulator during the power-on sequence according to some implementations of the present invention, overcurrent may be prevented and malfunction of the electronic device may be reduced.

FIG. 19 is a flowchart illustrating a method of stabilizing an output voltage of a voltage regulator based on monitoring of the output voltage according to some implementations.

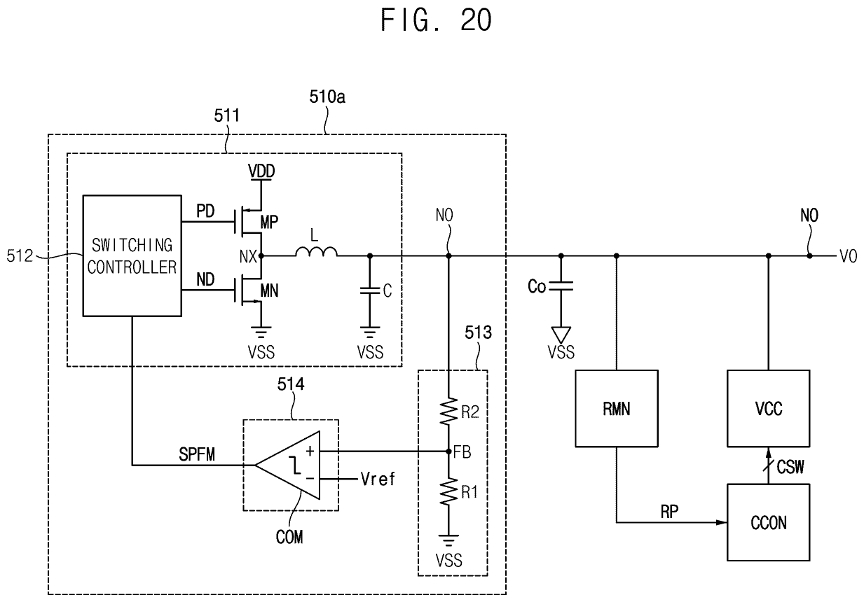

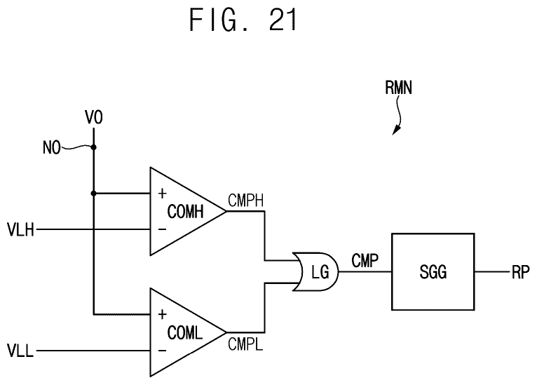

Referring to FIG. 19, the output voltage may be monitored to generate a ripple state signal indicating a fluctuation state of the output voltage of the voltage regulator (S41). For example, the ripple state signal may be generated using a ripple monitor as will be described below referring to FIGS. 20 and 21.

Based on the ripple state signal, the variable capacitance circuit may be controlled such that the capacitance of the output node of the voltage regulator increases sequentially as the fluctuation of the output voltage increases (S42).

FIG. 20 is a diagram illustrating an electronic device according to some implementations.

Referring to FIG. 20, an electronic device includes a voltage regulator 510a, an output capacitor Co, a variable capacitance circuit VCC, a capacitance controller CCON, and a ripple monitor RMN.

The voltage regulator 510a includes a voltage conversion circuit 511, a feedback circuit 513, and a voltage control circuit 514.

The voltage conversion circuit 511 converts the input voltage, for example, the power supply voltage VDD, based on a voltage control signal, for example, the PFM voltage control signal (SPFM), to generate an output voltage VO through an output node NO. The configuration of the voltage conversion circuit 511 in FIG. 20 corresponds to a buck converter.

The voltage conversion circuit 511 may be implemented including a switching controller 512, a pull-up transistor MP, a pull-down transistor MN, an inductor L, and a capacitor C.

The switching controller 512 may generate a pull-up control signal PD and a pull-down control signal ND based on the PFM voltage control signal SPFM.

The pull-up transistor MP may be turned on when the pull-up control signal PD is activated to a low level to pull up the voltage of the power switching node NX.

The pull-down transistor MN may be turned on when the pull-down control signal ND is activated to a high level to pull down the voltage of the power switching node NX.

The inductor L and capacitor C operate as a low-pass filter to filter the voltage of the power switching node NX and output the output voltage VO through the output node NO.

The configuration of the switching circuit including the pull-up transistor MP and the pull-down transistor MN, the low-pass filter including the inductor L and the capacitor C may be modified in various ways.

The voltage control circuit 514 generates the PFM voltage control signal SPFM based on a feedback voltage FB that is proportional to the output voltage VO. In some implementations, the voltage control circuit 514 may be implemented with a comparator COM. The feedback voltage FB is applied to the positive input terminal of the comparator COM, a reference voltage Vref is applied to the negative input terminal of the comparator COM, and the PFM voltage control signal (SPFM) may be generated through the output terminal of the comparator COM.

The feedback circuit 513 may generate the feedback voltage FB that is proportional to the output voltage VO. The feedback circuit 513 may provide the feedback voltage FB corresponding to the ratio of the resistance values using the division resistors R1 and R2, as shown in FIG. 20, but some implementations are not limited thereto. In the implementations of FIG. 20, the relationship FB=VO*R1/(R1+R2) is satisfied.

The voltage regulator 510a may convert the power supply voltage VDD corresponding to the input voltage VIN and generate the output voltage VO through the output node NO.

The output capacitor Co is connected to the output node NO and has a fixed capacitance.

The capacitance controller CCON may generate a plurality of capacitance control signals CSW based on the ripple status signal RP corresponding to the status signal STS.

The variable capacitance circuit VCC is connected to the output node NO and has a capacitance that changes based on the plurality of capacitance control signals CSW.

The ripple monitor RMN may monitor the output voltage VO of the voltage regulator 510a and generate the ripple state signal RP indicating a variation of the output voltage VO.

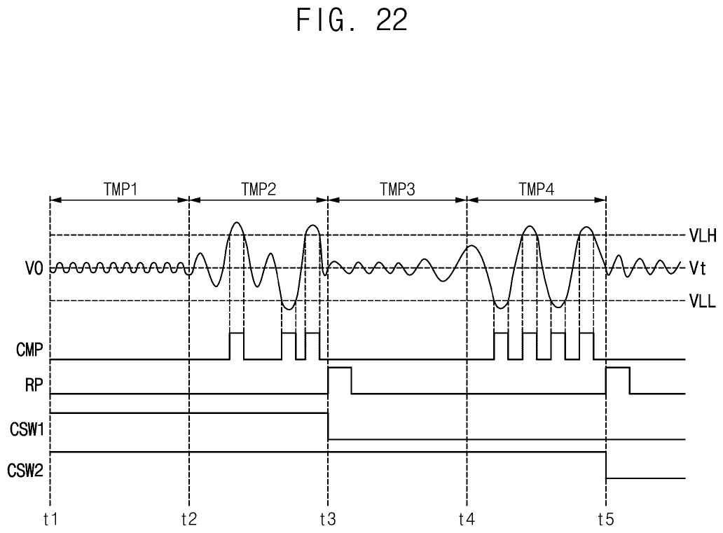

FIG. 21 is a diagram illustrating some implementations of a ripple monitor included in the electronic device of FIG. 20, and FIG. 22 is a timing diagram illustrating an operation of the electronic device of FIG. 20.

Referring to FIG. 21, the ripple monitor RMN includes a first comparator (or a high limit comparator) COMH, a second comparator (or a low limit comparator) COML, a logic gate LG, and a signal generator SGG.

The positive input terminal (+) of the first comparator COMH may be applied with the output voltage VO of the voltage regulator, and the negative input terminal (−) of the first comparator COMH may be applied with a first reference voltage VLH. The first comparator COMH may compare the output voltage VO with the first reference voltage VLH to generate a first comparison signal CMPH.

The positive input terminal (+) of the second comparator COML may be applied with the output voltage VO and the negative input terminal (−) of the second comparator COML may be applied with a second reference voltage VLL that is lower than the first reference voltage VLH. The second comparator COML may compare the output voltage VO with and the second reference voltage VLL to generate a second comparison signal CMPL.

The logic gate LG may perform a logic operation on the first comparison signal CMPH and the second comparison signal CMPL to generate a comparison signal CMP. For example, the first comparison signal CMPH and the second comparison signal CMPL may be activated at a logic high level. In this case, the logic gate LG may be implemented as a logic OR gate.

Based on the comparison signal CMP, the signal generator SGG may generate the ripple state signal RP indicating a variation state of the output voltage VO.

FIG. 22 illustrates an example of fluctuation of the output voltage VO. The ripple monitor RMN of FIG. 21 may utilize the first comparator COMH, the second comparator COML, and the logic gate LG to generate the compare signal CMP that is activated to a logic high level during intervals while the output voltage VO is greater than the first reference voltage VLH or less than the second reference voltage VLL.

In some implementations, the signal generator SGG of the ripple monitor RMN may periodically determine whether to activate the ripple state signal RP based on the comparison signal CMP. As shown in FIG. 22, the ripple monitor RMN may determine whether the variation of the output voltage VO is greater than a reference based on the comparison signal CMP per each of the plurality of monitoring intervals TMP1˜TMP4 between the time points t1˜t5.

For example, the ripple state signal RP may not be activated at the end points t2 and t4 of the first and third monitoring periods TMP1 and TMP3 because the variation of the output voltage VO in the first monitoring period TMP1 and the third monitoring period TMP3 is smaller than the reference. On the other hand, since the variation of the output voltage VO in the second and fourth monitoring periods TMP2 and TMP4 is greater than the reference, the ripple state signal RP may be activated to a logic high level at the end points t3 and t5 of the second and fourth monitoring periods TMP2 and TMP4.

The capacitance controller CCON of FIG. 20 may sequentially increase the capacitance of the output node NO of the voltage regulator VR in response to the activation of the ripple state signal RP corresponding to the aforementioned state signal STS.

For example, the capacitance controller CCON may activate the first capacitance control signal CSW1 to a logic low level in response to the activation of the ripple state signal RP at time point t3 to electrically connect the first capacitor C1 of the first capacitor group CG1 to the output node NO. The capacitance controller CCON may then activate the second capacitance control signal CSW2 to a logic low level in response to the activation of the ripple state signal RP at time point t5 to electrically connect the second capacitor C2 of the second capacitor group CG2 to the output node NO.

In this way, the capacitance controller CCON may control the variable capacitance circuit VCC based on the ripple state signal RP such that the capacitance of the output node NO increases sequentially as the fluctuation of the output voltage VO increases.

FIG. 23 is a block diagram illustrating some implementations of a temperature measurement circuit included in an electronic device according to some implementations, and FIG. 24 is a circuit diagram illustrating some implementations of a temperature detector included in the temperature measurement circuit of FIG. 23.

Referring to FIG. 23, a temperature measurement circuit 700 includes a temperature detector (DET) 710 and an analog-to-digital convertor (CNV) 720. The temperature detector 710 may output at least one of a voltage signal VPTAT and a current signal IPTAT proportional to the operation temperature To. The analog-to-digital converter 720 may convert the output of the temperature detector 710 to a digital signal to generate a temperature code TCODE of multiple bits.

In some implementations, the temperature detector 710 may be implemented with first and second PMOS transistors M1 (with current I1), M2 (with current I2), a feedback amplifier AMP, a resistor R and first and second bipolar transistors B1, B2, which are coupled between a power supply voltage VDD and a ground voltage VSS as represented in FIG. 24. A voltage dVBE across the resistor R may be obtained as Expression 1.

$$\begin{matrix}dVBE = VBE 1 - VBE 2 \\ = VT ⋆ Ln ( Ic 1 / Is 1 ) - VT ⋆ Ln ( n ⋆ Ic 2 / Is 2 ) \\ = VT ⋆ Ln ( n )\end{matrix} \qquad ( Expression 1 )$$

In Expression 1, Is1 and Is2 indicate reverse saturation currents of the bipolar transistors B1, B2, respectively. Also, Ic1 and Ic2 indicate currents flowing through the bipolar transistors B1, B2, respectively. Additionally, n is a gain ratio of the bipolar transistors B1, B2, and VT indicates a temperature voltage that is proportional to an absolute temperature of the temperature detector 710. Ln(n) is a constant value and thus the voltage dVBE across the resistor R and the current I2 flowing through the resistor R are proportional to the temperature variation. The voltage signal VPTAT and the current signal IPTAT may be generated as an output based on the voltage dVBE and the current I2 proportional to the operation temperature.

The on-chip temperature sensor described with reference to FIGS. 23 and 24 may be integrated in the same semiconductor die of an electronic device such as a storage device. Using the temperature measurement circuit 100 as described with reference to FIGS. 23 and 24, the operation temperature To of the electronic device may be measured accurately.

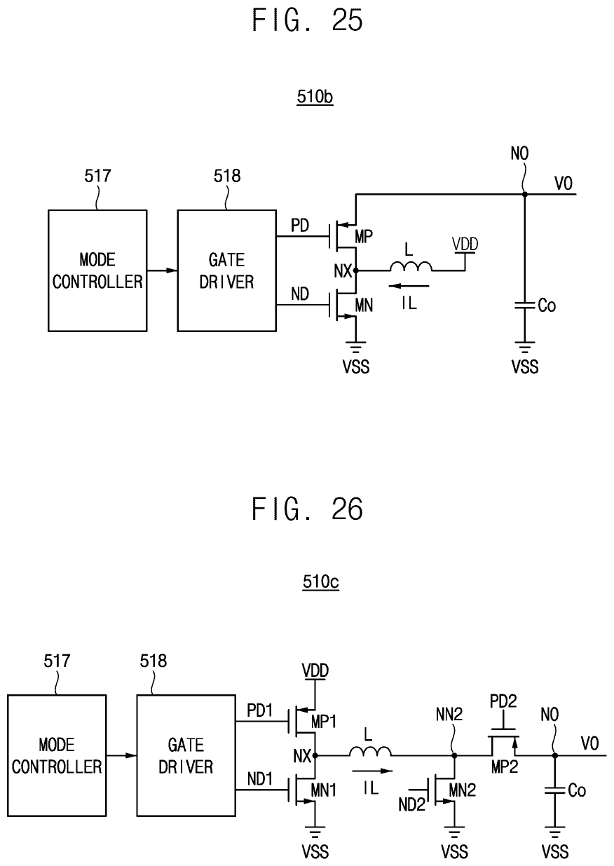

FIGS. 25 and 26 are diagrams illustrating a voltage regulator according to some implementations.

Referring to FIGS. 25 and 26, a mode controller 517 of voltage regulators 510b and 510c may control a gate driver 518 to selectively operate in a pulse-width modulation (PWM) mode or a pulse-frequency modulation (PFM) mode. The switching controller or the gate driver 518 may generate a pull-up control signal PD and a pull-down control signal ND based on a PFM voltage control signal SPFM or a PWM voltage control signal, as described above with reference to FIG. 20.

The conversion circuit corresponding to the boost converter of FIG. 25 has a different connection relationship between the transistors MP and MN and the inductor L compared to the conversion circuit 510a of FIG. 20. By the switching operation of the transistors MP and MN, power may be supplied to the output node NO through the current IL of the inductor L, and the output voltage VO may be boosted to a voltage level higher than the power supply voltage VDD.

The conversion circuit corresponding to the buck-boost converter in FIG. 26 further includes transistors MP2 and MN2 compared to the conversion circuit 510a in FIG. 20, and connections among the transistors MP1, MN1, MP2 and MN and the inductor L are different. By the switching operation of the transistors MP1, MN1, MP2, and MN1, the conversion circuit may generate an output voltage VO having a voltage level lower or higher than the power supply voltage VDD at the output node NO.

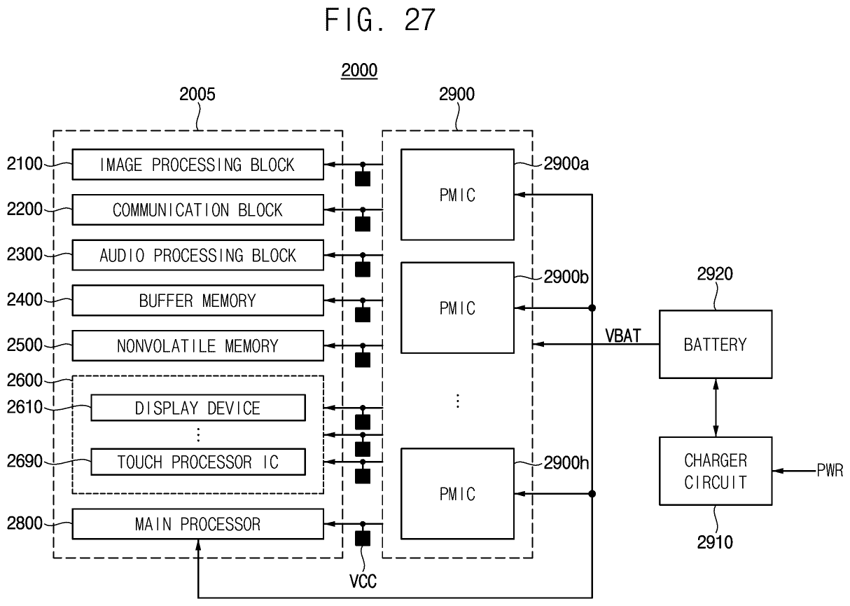

FIG. 27 is a diagram illustrating an electronic device according to some implementations.

Referring to FIG. 27, an electronic device 2000 includes various load devices 2005, a power management device 2900, a battery 2920, and a charger circuit 2910. For example, the load devices 2005 include an image processing block 2100, a communication block 2200, an audio processing block 2300, a buffer memory 2400, a nonvolatile memory 2500, a user interface 2600. The user interface 2600 includes a main processor 2800, a display device 2610, a touch processor integrated circuit (IC) 2620, and the like.

The power management device 2900 may supply power to the load devices 2005 of the electronic device 2000 through voltage (power) rails. For example, the charger circuit 2910 may charge the battery 2920 based on the power PWR received from the outside, and the battery 2920 may provide the battery voltage VBAT as the input voltage of the power management device 2900 based on the charged voltage.

The power management device 2900 may output power to be supplied to components of the electronic device 2000 based on the battery voltage VBAT. The power management device 2900 may appropriately convert the system voltage and transfer the obtained power to the components of the electronic device 2000.

In some implementations, the power management device 2900 includes a plurality of PMICs 2900a, 2900b, . . . , 2900h, and each of the plurality of PMICs 2900a, 2900b, . . . , 2900h is configured to supply power to at least one component of the electronic device 2000. For example, the voltage output from each of the voltage regulators in the plurality of PMICs 2900a, 2900b, . . . , 2900h may be provided to at least one of the image processing block 2100, the communication block 2200, the audio processing block 2300, the buffer memory 2400, the nonvolatile memory 2500, the user interface 2600, and the main processor 2800. The load devices 2005 of the electronic device 2000 may operate based on the provided voltage.

The voltage generated from the plurality of PMICs 2900a, 2900b, . . . , 2900h may be transmitted to the load devices 2005 or the transmission may be blocked in a predetermined order. To this end, the plurality of PMICs 2900a, 2900b, . . . , 2900h may be synchronized with each other during the power-on sequence and the power-off sequence.

Before performing the power-on sequence, a main PMIC corresponding to one of the plurality of PMICs 2900a, 2900b, . . . , 2900h may activate first functions related to the first initial operation based on the battery voltage VBAT in the standby period. After the first initial operation is completed, a sub-enable signal may be sent to sub PMICs excluding the main PMIC among the plurality of PMICs 2900a, 2900b, . . . , 2900h based on the power-on signal provided from the outside. The sub PMICs may receive the sub-enable signal, and in response to activation of the sub-enable signal, a second function related to a second initial operation based on the battery voltage VBAT may be activated. Therefore, the standby current consumed during the standby period of the power management device 2900 may be reduced.

A variable capacitance circuit VCC according to some implementations of the present invention may be connected to each output node of the plurality of PMICs 1900a, 1900b, . . . , 1900h. The plurality of PMICs 1900a, 1900b, . . . , 1900h may control the capacitance of the variable capacitance circuit VCC by providing capacitance control signals as described above to the corresponding variable capacitance circuit VCC.

As described above, the method of stabilizing the output voltage of the voltage regulator according to some implementations may prevent abnormal operations and enhance performance of the electronic device including the voltage regulator by changing the capacitance of the output node of the voltage regulator depending on the operation state of the electronic device using the variable capacitance circuit.

Those skilled in the art will understand that the capacitance controller according to some implementations may be implemented in the form of system, method, product including computer-readable program code stored in a computer-readable medium, etc. The computer-readable program code may be provided to a processor of various computers or other data processing devices. The computer-readable medium may be a computer-readable signal medium or a computer-readable recording medium. The computer-readable recording medium may be any tangible medium capable of storing or containing a program in or connected to an instruction execution system, equipment, or device.

Some implementations may be applied to any electronic devices and systems. For example, the disclosure may be applied to systems such as a memory card, a solid state drive (SSD), an embedded multimedia card (eMMC), a universal flash storage (UFS), a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, a server system, an automotive driving system, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of some implementations and is not to be construed as limiting thereof. Although a few implementations have been described, those skilled in the art will readily appreciate that many modifications are possible in the implementations without materially departing from the present disclosure.

What is claimed is:

1. An electronic device comprising:
a voltage regulator configured to convert an input voltage to generate an output voltage through an output node;
a load device configured to receive the output voltage;
an output capacitor connected to the output node, the output capacitor having a fixed capacitance;
a capacitance controller configured to generate a plurality of capacitance control signals based on a state signal indicating an operation state of the electronic device; and
a variable capacitance circuit connected to the output node, the variable capacitance circuit having a capacitance that changes based on the plurality of capacitance control signals.

2. The electronic device of claim 1,
wherein the state signal corresponds to a temperature code indicating an operation temperature of the electronic device, and
wherein the capacitance controller is configured to control the variable capacitance circuit based on the temperature code such that a capacitance of the output node increases as the operation temperature increases.

3. The electronic device of claim 1,
wherein the electronic device comprises a storage device, wherein the load device comprises a nonvolatile memory device and a storage controller configured to control the nonvolatile memory device,
wherein the state signal comprises a queue state signal indicating an occupation number of commands stored in a command queue of the storage controller, and
wherein the capacitance controller is configured to control the variable capacitance circuit based on the queue state signal such that a capacitance of the output node increases as the occupation number increases.

4. The electronic device of claim 1,
wherein the state signal comprises a power-on signal indicating a start of a power-sequence of the electronic device, and
wherein the capacitance controller is configured to control the variable capacitance circuit based on the power-on signal such that a capacitance of the output node increases sequentially while the electronic device is powered on.

5. The electronic device of claim 1,
wherein the state signal comprises a ripple state signal indicating a variation of the output voltage, and
wherein the capacitance controller is configured to control the variable capacitance circuit based on the ripple state signal such that a capacitance of the output node increases as the variation of the output voltage increases.

6. The electronic device of claim 1,
wherein the variable capacitance circuit includes a plurality of capacitor groups connected in parallel to the output node and configured to receive the plurality of capacitance control signals, respectively, and
wherein each capacitor group of the plurality of capacitor groups includes:
a capacitor; and
a switch configured to electrically connect the capacitor to the output node based on activation of a capacitance control signal of the plurality of capacitance control signals.

7. The electronic device of claim 6,
wherein the capacitance controller is configured to sequentially activate the plurality of capacitance control signals based on the state signal, and
wherein the variable capacitance circuit is configured to sequentially increase a capacitance of the output node based on the plurality of capacitance control signals that are activated sequentially.

8. The electronic device of claim 6, wherein the switch includes:
a first transistor connected between the output node and the capacitor and having a gate electrode configured to receive the capacitance control signal; and
a second transistor connected between the output node and the capacitor in parallel with the first transistor and having a drain electrode and a gate electrode that are electrically connected to each other.

9. The electronic device of claim 6,
wherein the state signal comprises a temperature code indicating an operation temperature of the electronic device,
wherein the operation temperature is divided into a plurality of operation temperature intervals, and
wherein the capacitance controller is configured to activate one or more capacitance control signals according to a temperature code such that:
a number of activated capacitance control signals increases from an earlier operation temperature interval to a later operation temperature interval, and
a number of capacitor groups that are electrically connected to the output node increases from the earlier operation temperature interval to the later operation temperature interval as the operation temperature increases.

10. The electronic device of claim 6,
wherein the electronic device comprises a storage device,
wherein the load device comprises a nonvolatile memory device and a storage controller configured to control the nonvolatile memory device,
wherein the state signal comprises a queue state signal indicating an occupation number of commands that are stored in a command queue of the storage controller,
wherein the operation temperature is divided into a plurality of occupation number intervals, and
wherein the capacitance controller is configured to activate one or more capacitance control signals according to the queue state signal such that:
a number of activated capacitance control signals increases from an earlier occupation number interval to a later occupation number interval, and
a number of capacitor groups that are electrically connected to the output node increases from the earlier occupation number interval to the later occupation number interval as the occupation number increases.

11. The electronic device of claim 6,
wherein the state signal comprises a power-on signal indicating a start of a power-sequence of the electronic device, and
wherein the capacitance controller is configured to sequentially activate, based on the power-on signal, one or more capacitance control signals of the plurality of capacitance control signals such that a number of capacitor groups that are electrically connected to the output node increases sequentially while the electronic device is powered on.

12. The electronic device of claim 6,
wherein the state signal comprises a ripple state signal indicating a variation of the output voltage, and
wherein the capacitance controller is configured to sequentially increase, based on the ripple state signal, a number of capacitance control signals that are activated such that a number of capacitor groups that are electrically connected to the output node increases sequentially as the variation of the output voltage increases.

13. The electronic device of claim 1, wherein the capacitance controller is configured to increase a number of capacitance control signals that are activated such that a capacitance of the output node increases when an operation temperature of the electronic device increases to be higher than a first reference temperature, wherein the capacitance controller is configured to decrease the number of capacitance control signals that are activated such that the capacitance of the output node decreases when the operation temperature of the electronic device decreases to be lower than a second reference temperature, and wherein the second reference temperature is lower than the first reference temperature.

14. The electronic device of claim 1, further comprising:
a first comparator configured to generate a first comparison signal by comparing the output voltage with a first reference voltage;
a second comparator configured to generate a second comparison signal by comparing the output voltage with a second reference voltage;
a logic gate configured to generate a comparison signal by performing a logic operation on the first comparison signal and the second comparison signal; and
a signal generator configured to generate, based on the comparison signal, a ripple state signal indicating a variation of the output voltage.

15. A storage device comprising:
a nonvolatile memory device configured to store data;
a storage controller configured to control the nonvolatile memory device;
a voltage regulator configured to convert an input voltage to generate an output voltage through an output node, and configured to supply the output voltage to the nonvolatile memory device and the storage controller;
an output capacitor connected to the output node, the output capacitor having a fixed capacitance;
a capacitance controller configured to generate a plurality of capacitance control signals based on a state signal indicating an operation state of the electronic device; and
a variable capacitance circuit connected to the output node, the variable capacitance circuit having a capacitance that changes based on the plurality of capacitance control signals.

16. The storage device of claim 15, further comprising:
a temperature measurement circuit configured to measure an operation temperature of the storage device to generate a temperature code indicating the operation temperature,
wherein the capacitance controller is configured to control the variable capacitance circuit based on the temperature code such that a capacitance of the output node increases as the operation temperature increases.

17. The storage device of claim 15, wherein the storage controller includes:
a command queue configured to store command that are transferred from a host device; and
a queue manager configured to control the command queue and generate a queue state signal indicating an occupation number of commands stored in the command queue,
wherein the capacitance controller is configured to control the variable capacitance circuit based on the queue state signal such that a capacitance of the output node increases as the occupation number increases.

18. The storage device of claim 15, further comprising:
a power management circuit configured to monitor the input voltage to generate a power-on signal indicating a start of a power-sequence of the storage device,
wherein the capacitance controller is configured to control the variable capacitance circuit based on the power-on signal such that a capacitance of the output node increases sequentially while the storage device is powered on.

19. The storage device of claim 15, further comprising:
a ripple monitor configured to monitor the output voltage to generate a ripple state signal indicating a variation of the output voltage,
wherein the capacitance controller is configured to control the variable capacitance circuit based on the ripple state signal such that a capacitance of the output node increases as the variation of the output voltage increases.

20. A method of stabilizing an output voltage of a voltage regulator, comprising:
converting, using a voltage regulator, an input voltage to generate an output voltage through an output node of the voltage regulator;
generating a state signal indicating an operation state of an electronic device;
generating a plurality of capacitance control signals based on the state signal; and
changing, using a variable capacitance circuit connected to the output node, a capacitance of the output node based on the plurality of capacitance control signals.
